(19) United States
(12) Patent Application Publication
(10) Pub. No.: US 2026/0313808 A1
(43) Pub. Date: Oct. 8, 2026

(54) CIRCUIT BOARD PROCESSING EQUIPMENT

(71) Applicant: WISTRON CORPORATION, New Taipei City (TW)

(72) Inventors: Zeshan YAN, New Taipei City (TW); Shun Chi YEH, New Taipei City (TW); Fuhua YAN, New Taipei City (TW); Xiao Mei ZHANG, New Taipei City (TW)

(73) Assignee: WISTRON CORPORATION, New Taipei City (TW)

(21) Appl. No.: 19/208,930

(22) Filed: May 15, 2025

(30) Foreign Application Priority Data
Apr. 8, 2025 (CN) 202510437341.3

(51) Int. Cl. H05K 3/00

(52) U.S. Cl. CPC H05K 3/0008; H05K 2203/0165

(57) ABSTRACT

A circuit board processing equipment for a circuit board is provided in the disclosure. A protective cover and a dustproof film are provided on the circuit board. The circuit board processing equipment includes a base, a track portion and a circuit board processing device. The track portion is disposed on the base and is used to convey the circuit board. The circuit board processing device includes a driving part, a clamping claw and a tape assembly. The driving part is disposed on the base and coupled to the clamping claw and the tape assembly. The clamping claw is driven to remove the protective cover from the circuit board, and the tape assembly is driven to adhere the dustproof film and remove the dustproof film from the circuit board by the driving part.

### CROSS-REFERENCE TO RELATED APPLICATION

This application claims the priority and benefit of Chinese Application Serial No. 202510437341.3, filed on Apr 8, 2025, the disclosure of which is hereby incorporated in its entirety by reference herein.

### TECHNICAL FIELD

The disclosure relates to a circuit board processing equipment, and more particularly to a circuit board processing equipment for removing a protective cover and/or a dustproof film on a circuit board.

### BACKGROUND

### Description of Related Art

In the process of manufacturing printed circuit boards, in order to prevent contamination or damage to electronic elements on the circuit board, a protective cover is temporarily placed over the electronic elements or a dustproof film is applied thereto. The operator is required to manually remove the protective cover from the circuit board and manually peel off the dustproof film.

### SUMMARY

A circuit board processing equipment, which removes a protective cover and/or peel off a dustproof film from a circuit board, is provided in the disclosure.

The circuit board processing equipment of the disclosure is used for a circuit board. A protective cover and a dustproof film are provided on the circuit board. The circuit board processing equipment includes a base, a track portion and a circuit board processing device. The track portion is disposed on the base and is used to convey the circuit board. The circuit board processing device includes a driving part, a clamping claw and a tape assembly. The driving part is disposed on the base and is coupled to the clamping claw and the tape assembly. The clamping claw is driven to remove the protective cover from the circuit board, and the tape assembly is driven to adhere the dustproof film and remove the dustproof film from the circuit board by the driving part.

In one embodiment of the disclosure, the driving part includes a robotic arm, and the clamping claw and the tape assembly are coupled to the same robotic arm.

In one embodiment of the disclosure, the driving part includes a bracket, the bracket includes two frames respectively extending in different directions, and the clamping claw and the tape assembly are respectively disposed on the two frames.

In one embodiment of the disclosure, the robotic arm is coupled to the clamping claw and the clamping claw is driven to move corresponding to the protective cover.

In one embodiment of the disclosure, the driving part includes a cylinder connected to the clamping claw and the clamping claw is driven to clamp the protective cover.

In one embodiment of the disclosure, the protective cover includes multiple protective covers, the clamping claw include multiple clamping claws, the cylinder includes multiple cylinders, and the cylinders are respectively connected to the clamping claws. The robotic arm is used to drive the clamping claws to move above the protective covers, and control the clamping claws through the cylinders to sequentially remove the protective covers from the circuit board.

In one embodiment of the disclosure, the driving part includes an arc-shaped frame, and the clamping claws are sequentially disposed on the arc-shaped frame.

In one embodiment of the disclosure, the circuit board processing equipment further includes a driving device. The track portion includes two tracks, and the driving device is connected to the track portion and the two tracks are driven to move relative to each other to adjust a distance between the two tracks by the driving device.

In one embodiment of the disclosure, the circuit board processing equipment further includes a clamping device and a driving device. The clamping device is disposed on the track portion, and the driving device is connected to the clamping device and the clamping device is driven to clamp the circuit board on the track portion by the driving device.

In one embodiment of the disclosure, the circuit board processing equipment further includes a waste box. The waste box is disposed on the base, the clamping claw is driven to move the protective cover into the waste box by the driving part.

In one embodiment of the disclosure, the robotic arm is coupled to the tape assembly and the tape assembly is driven to move corresponding to the dustproof film by the robotic arm.

In one embodiment of the disclosure, the tape assembly includes a feed reel, a recovery reel, a tape support and a tape. The tape is partially wound around the feed reel and the recovery reel, and a portion of the tape located between the feed reel and the recovery reel is supported by the tape support.

In one embodiment of the disclosure, the tape support is provided with a support plane, and the tape is supported by the support plane.

In one embodiment of the disclosure, the driving part includes a motor connected to the recovery reel and the recovery reel is driven by the motor to rotate so as to drive different portions of the tape to be supported by the tape support in sequence.

In one embodiment of the disclosure, the tape assembly further includes a sensing device, which is used to sense whether the tape is supported by the tape support.

In one embodiment of the disclosure, the sensing device includes an optical sensor disposed between the tape support and one of the feed reel or the recovery reel.

The circuit board processing equipment of the disclosure is used for a circuit board. A protective cover is provided on the circuit board. The circuit board processing equipment includes a base, a track portion, a circuit board processing device and a waste box. The track portion is disposed on the base and is used to convey the circuit board. The circuit board processing device includes a driving part and multiple clamping claws. The waste box is disposed on the base and adjacent to the track portion. The driving part is disposed on the base and coupled to the clamping claws. The clamping claws are driven to remove the protective cover from the circuit board and place the protective cover in the waste box by the driving part.

In one embodiment of the disclosure, the driving part includes an arc-shaped frame, and the clamping claws are sequentially disposed on the arc-shaped frame.

The circuit board processing equipment of the disclosure is used for a circuit board. A dustproof film is provided on the circuit board. The circuit board processing equipment includes a base, a track portion and a circuit board processing device. The track portion is disposed on the base and is used to convey the circuit board. The circuit board processing device includes a driving part and a tape assembly. The driving part is disposed on the base and coupled to the tape assembly, and the tape assembly is driven to adhere the dustproof film and remove the dustproof film from the circuit board by the driving part.

In one embodiment of the disclosure, the tape assembly includes a feed reel, a recovery reel, a tape support and a tape. The tape is partially wound around the feed reel and the recovery reel, and a portion of the tape located between the feed reel and the recovery reel is supported by the tape support.

### BRIEF DESCRIPTION OF THE DRAWINGS

FIG. 1 is a top view of a circuit board processing apparatus of an embodiment of the disclosure.

FIG. 2 is a partial cross-sectional schematic diagram of the circuit board of FIG. 1.

FIG. 3 is a three-dimensional diagram of some components of the circuit board processing device of FIG. 1.

FIG. 4 is a side view of some components of the circuit board processing device of FIG. 1.

FIG. 5A and FIG. 5B illustrate the process of the clamping claw of FIG. 3 clamping the protective cover of FIG. 2.

FIG. 6A and FIG. 6B illustrate the process of the tape assembly of FIG. 3 adhering the dustproof film of FIG. 2.

FIG. 7 is a side view of the circuit board processing device of FIG. 3.

FIG. 8 is a three-dimensional diagram of the tape support of FIG. 7.

FIG. 9 is a partial three-dimensional diagram of the circuit board processing equipment of FIG. 1.

FIG. 10A, FIG. 10B, FIG. 10C, and FIG. 10D illustrate the operation process of the circuit board processing equipment of FIG. 1.

### DETAILED DESCRIPTION

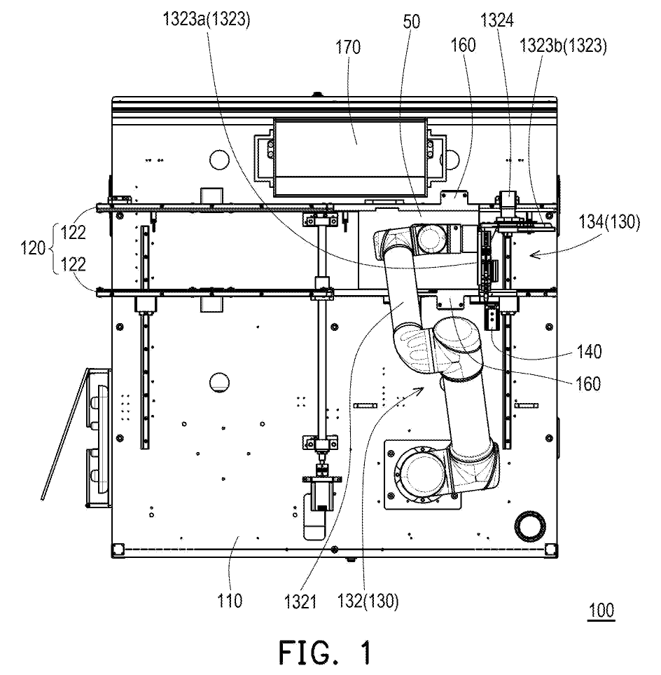

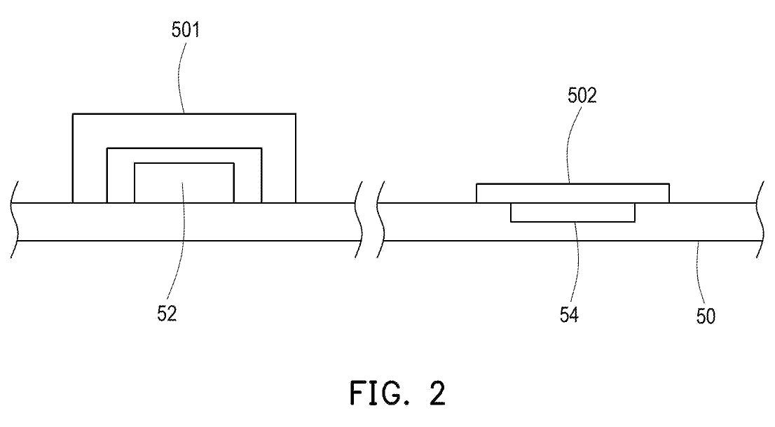

FIG. 1 is a top view of a circuit board processing apparatus of an embodiment of the disclosure. FIG. 2 is a partial cross-sectional schematic diagram of the circuit board of FIG. 1. Referring to FIG. 1 and FIG. 2, the circuit board processing equipment 100 of this embodiment is used to process a circuit board 50. The circuit board 50 has at least two electronic elements 52 and 54 and at least one protective cover 501 and at least one dustproof film 502 respectively covering the two electronic elements 52 and 54. The circuit board processing equipment 100 includes a base 110, a track portion 120 and a circuit board processing device 130. The track portion 120 is disposed on the base 110 and is used to convey the circuit board 50. The circuit board processing device 130 includes a driving part (a.k.a. driving device) 132 and a circuit board processing module 134. The driving part 132 is disposed on the base 110 and is coupled to the circuit board processing module 134.

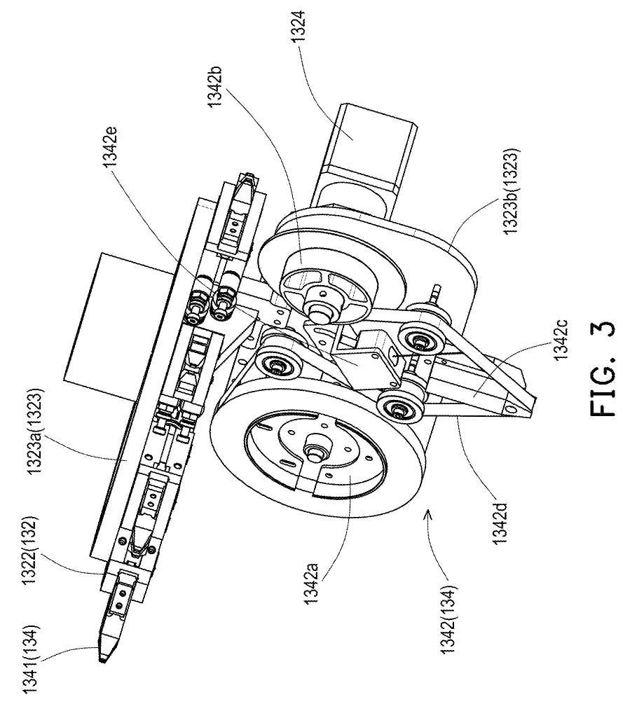

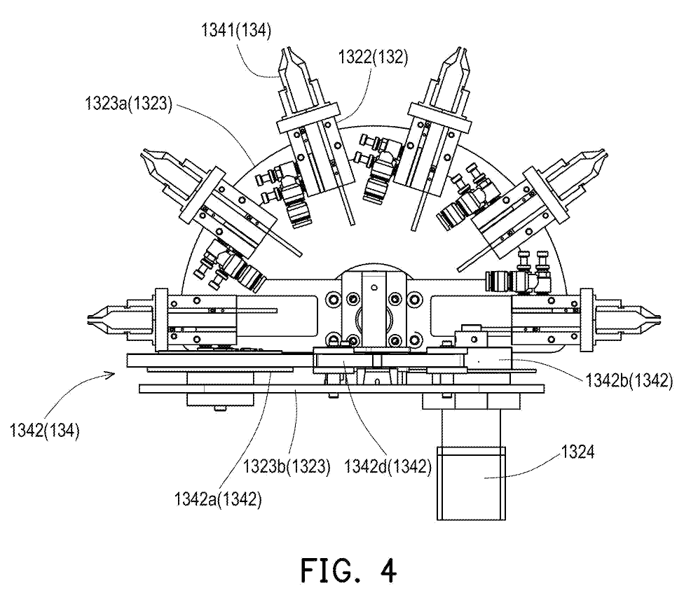

FIG. 3 is a three-dimensional diagram of some components of the circuit board processing device of FIG. 1. FIG. 4 is a side view of some components of the circuit board processing device of FIG. 1. Referring to FIG. 3 and FIG. 4, the circuit board processing module 134 of this embodiment includes multiple clamping claws 1341 and a tape assembly 1342. The driving part 132 (shown in FIG. 1) is coupled to the clamping claws 1341 and the tape assembly 1342 and the clamping claws 1341 and the tape assembly 1342 are driven by the driving part 132 to actuate.

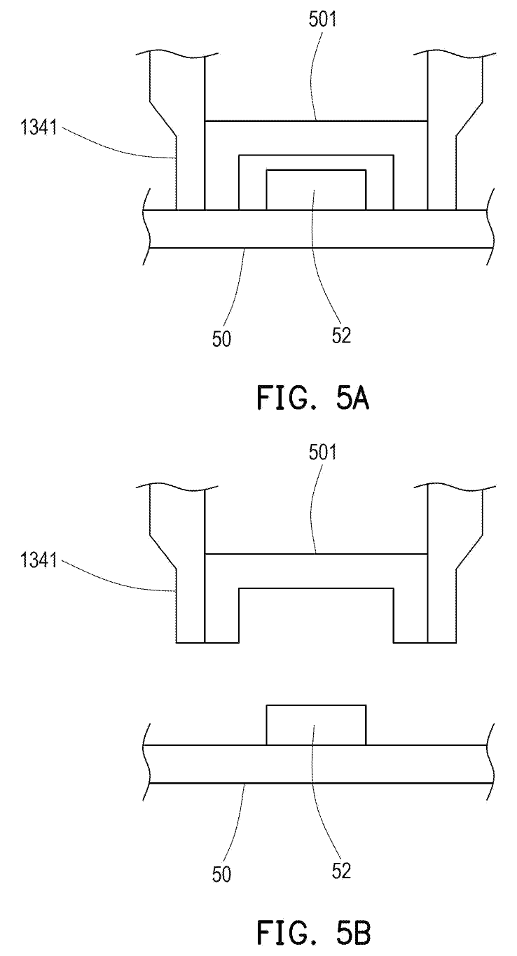

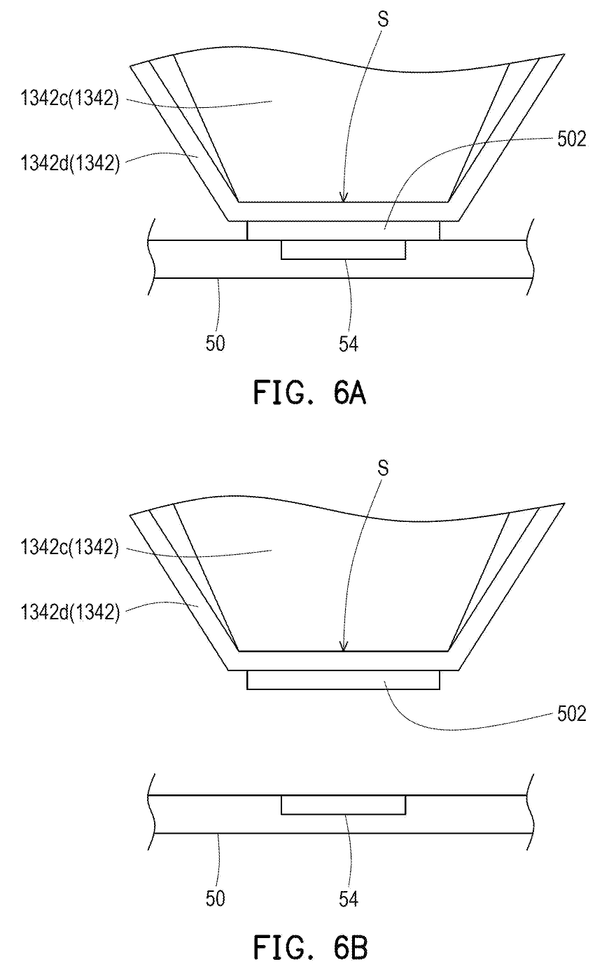

FIG. 5A and FIG. 5B illustrate the process of the clamping claw of FIG. 3 clamping the protective cover of FIG. 2. FIG. 6A and FIG. 6B illustrate the process of the tape assembly of FIG. 3 adhering the dustproof film of FIG. 2. Specifically, the clamping claws 1341 are driven by the driving part 132 to clamp the protective cover 501 as shown in FIG. 5A and to remove the protective cover 501 from the circuit board 50 as shown in FIG. 5B. In addition, t the tape assembly 1342 is driven by the driving part 132 to adhere the dustproof film 502 as shown in FIG. 6A and remove the dustproof film 502 from the circuit board 50.

As described above, the circuit board processing equipment 100 of this embodiment automatically drives the clamping claw 1341 to remove the protective cover 501 on the circuit board 50 through the driving part 132, and/or automatically drives the tape assembly 1342 to peel off the dustproof film 502 on the circuit board 50 through the driving part 132. Accordingly, there is no need to manually remove the protective cover 501 and peel off the dustproof film 502, and the efficiency of processing the circuit board 50 may be improved.

In detail, the driving part 132 of this embodiment includes a robotic arm 1321 as shown in FIG. 1 and includes a bracket 1323 as shown in FIG. 3 and FIG. 4. The bracket 1323 is disposed at the end of the robotic arm 1321 and includes two frames 1323a and 1323b respectively extending in different directions. The clamping claws 1341 are disposed on the frame 1323a, and the tape assembly 1342 is disposed on the frame 1323b, that is, the clamping claws 1341 and the tape assembly 1342 extend in different directions. The robotic arm 1321 is coupled to the clamping claws 1341 (shown in FIG. 3 and FIG. 4) and the tape assembly 1342 through the bracket 1323, and the clamping claws 1341 are driven by the robotic arm 1321 to move to a position corresponding to the protective cover 501 (shown in FIG. 2), and the tape assembly 1342 is driven by the robotic arm 1321 to move to a position corresponding to the dustproof film 502 (shown in FIG. 2). That is, the clamping claws 1341 and the tape assembly 1342 are coupled to the same robotic arm 1321 and are driven by the actuation of the same robotic arm 1321.

The driving part 132 of this embodiment further includes multiple cylinders 1322 as shown in FIG. 3 and FIG. 4. The cylinders 1322 are respectively connected to the clamping claws 1341. The corresponding clamping claw 1341 is driven by each cylinder 1322 to clamp the protective cover 501 as shown in FIG. 5A. The clamping claw 1341 is driven by the robotic arm 1321 to remove the protective cover 501 from the circuit board 50 as shown in FIG. 5B. When there are multiple protective covers 501, the driving part 132 may drive the clamping claws 1341 to sequentially clamp the protective covers 501 away from the circuit board 50 to improve the operation efficiency. Furthermore, the frame 1323a of the driving part 132 is an arc-shaped frame as shown in FIG. 4, and the clamping claws 1341 are arranged along the arc-shaped frame (frame 1323a), so that the robotic arm 1321 of the driving part 132 may quickly drive the clamping claws 1341 to sequentially approach the positions of the protective covers 501 on the circuit board 50. For example, after one of the clamping claws 1341 has clamped one of the protective covers 501, the robotic arm 1321 may rotatably adjust the angle of the frame 1323a relative to the circuit board 50, so that another clamping claw 1341 approaches another protective cover 501, thereby removing the other protective cover 501 from the circuit board 50.

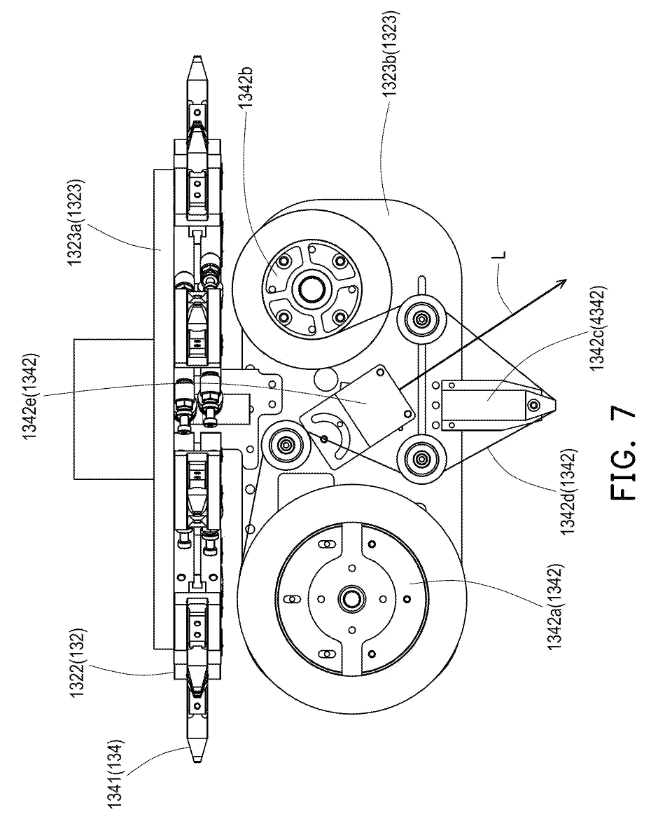

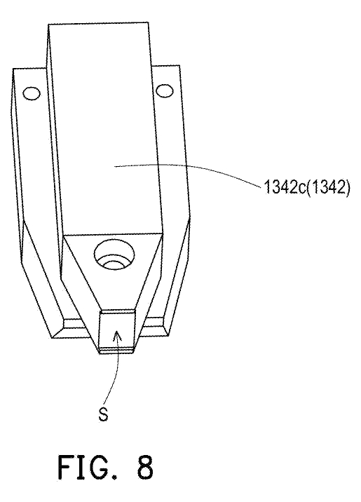

FIG. 7 is a side view of the circuit board processing device of FIG. 3. FIG. 8 is a three-dimensional diagram of the tape support of FIG. 7. Referring to FIG. 7 and FIG. 8, the tape assembly 1342 of this embodiment includes a feed reel 1342a, a recovery reel 1342b, a tape support 1342c and a tape 1342d. The tape 1342d is partially wound around the feed reel 1342a and the recovery reel 1342b, and the portion of the tape 1342d between the feed reel 1342a and the recovery reel 1342b is supported by the support plane S of the tape support 1342c to adhere the dustproof film 502 as shown in FIG. 6A.

In addition, in this embodiment, the driving part 132 includes a motor 1324 as shown in FIG. 3 and FIG. 4. The motor 1324 is connected to the recovery reel 1342b and the recovery reel 1342b is driven by the motor 1324 to rotate so as to drive the tape 1342d to be wound onto the recovery reel 1342b, so that different portions of the tape 1342d are supported by the tape support 1342c in sequence. For example, after a portion of the tape 1342d is supported by the tape support 1342c and adhered with a dustproof film 502, the portion of the tape 1342d adhered with the dustproof film 502 is removed from the tape support 1342c as the recovery reel 1342b rotates. Another portion of the tape 1342d is supported by the tape support 1342c as the recovery reel 1342b rotates and is used to adhere another dustproof film 502. At this time, the robotic arm 1321 may movably adjust the position of the frame 1323b relative to the circuit board 50, so that different portions of the tape 1342d are sequentially adhered to multiple dustproof films 502.

Furthermore, the tape assembly 1342 of this embodiment further includes a sensing device 1342e (shown in FIG. 3 and FIG. 7). The sensing device 1342e is disposed on the frame 1323b and located between the recovery reel 1342b and the tape support 1342c to sense whether the tape 1342d is exhausted. Specifically, the sensing device 1342e is, for example, an optical sensor, and the optical path L of the optical sensor passes through the tape conveying path between the tape support 1342c and the recovery reel 1342b as shown in FIG. 7. Accordingly, when the tape 1342d on the feed reel 1342a is gradually wound up onto the recovery reel 1342b until the tape 1342d at the tape conveying path through which the optical path L passes is the end of the tape without an adhesive layer, the optical sensor may determine that the tape 1342d is exhausted by changes in its transmittance or other optical properties. In other embodiments, whether the tape 1342d is exhausted may be sensed through other appropriate sensing methods, and the disclosure is not limited thereto.

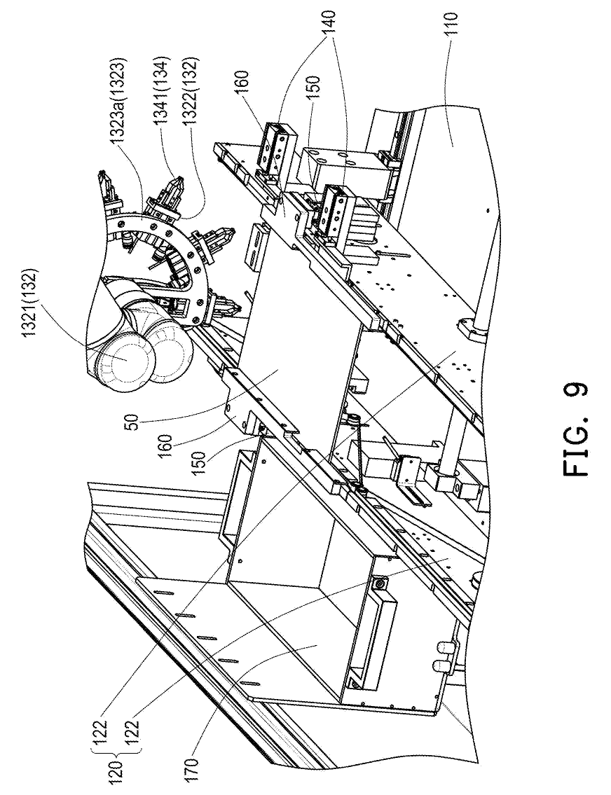

FIG. 9 is a partial three-dimensional diagram of the circuit board processing equipment of FIG. 1. Referring to FIG. 9, the track portion 120 of this embodiment includes two tracks 122. The two opposite sides of the circuit board 50 may be respectively supported by the two tracks 122. The circuit board processing equipment 100 further includes at least one driving device 140 (two are shown), which is connected to the track portion 120 and the two tracks 122 are driven by the driving devices 140 to move relative to each other to adjust the distance between the two tracks 122 so that the track portion 120 may support circuit boards of various widths. In this embodiment, the driving device 140 is, for example, a cylinder, which is used to drive one of the two tracks 122 to move relative to the other of the two tracks 122. In other embodiments, the distance between the two tracks 122 may be adjusted by other types of driving devices, and the disclosure is not limited thereto.

In addition, the circuit board processing equipment 100 of this embodiment further includes at least one clamping device (a.k.a. clamping device) 160 (two are shown) and at least one driving device 150 (two are shown). The clamping device 160 is disposed on the track portion 120. The driving device 150 is connected to the clamping device 160 and the clamping device 160 is driven by the driving device 150 to clamp the circuit board 50 on the track portion 120 to fix the circuit board 50. Accordingly, it is possible to prevent the circuit board processing module 134 from accidentally moving the circuit board 50 during operation. In this embodiment, the driving device 150 is, for example, a cylinder. In other embodiments, the clamping device 160 may be driven by other types of driving devices, and the disclosure is not limited thereto.

In this embodiment, the circuit board processing equipment 100 further includes a waste box 170. The waste box 170 is disposed on the base 110 and is adjacent to the track portion 120. The waste box 170 is used to accommodate the protective cover 501 clamped by the clamping claw 1341. Specifically, the robotic arm 1321 of the driving part 132 is used to move the circuit board processing module 134 above the waste box 170, and rotatably drive the clamping claws 1341 to sequentially move the clamped protective covers 501 (shown in FIG. 5B) into the waste box 170. Accordingly, it is possible to prevent the protective covers 501 from being scattered in the working area.

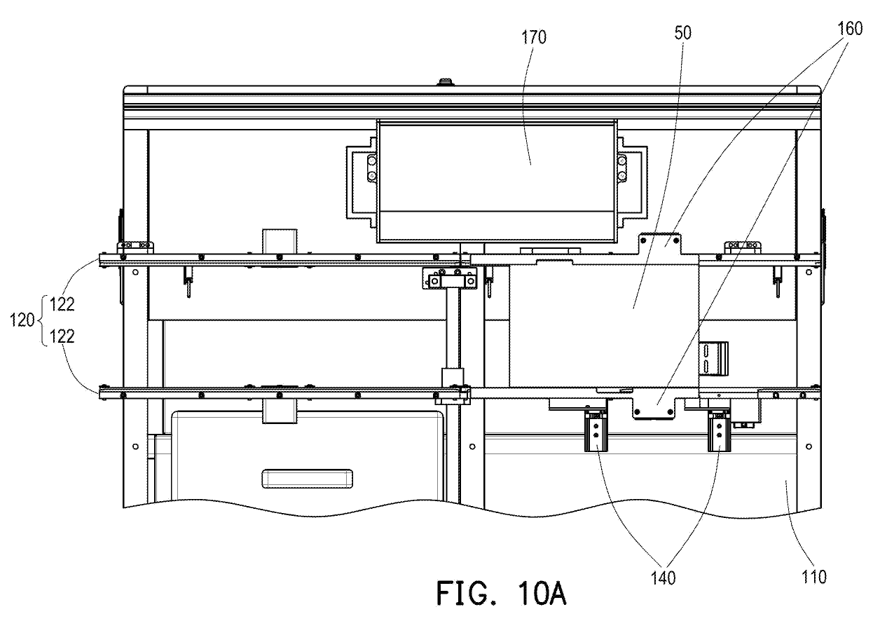

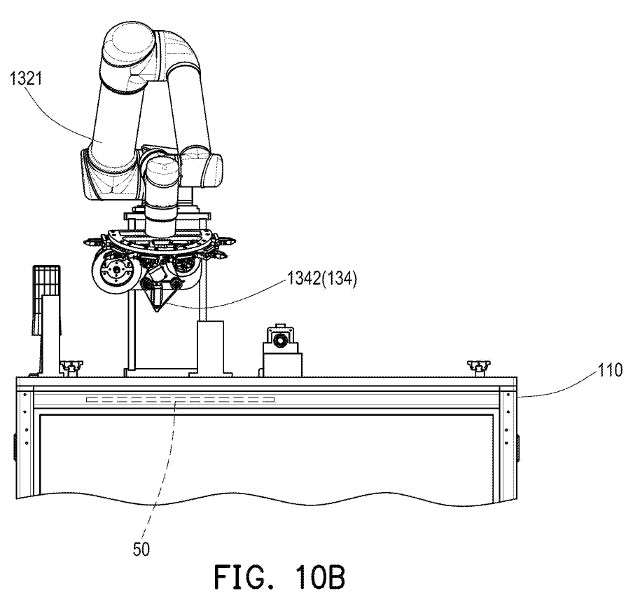

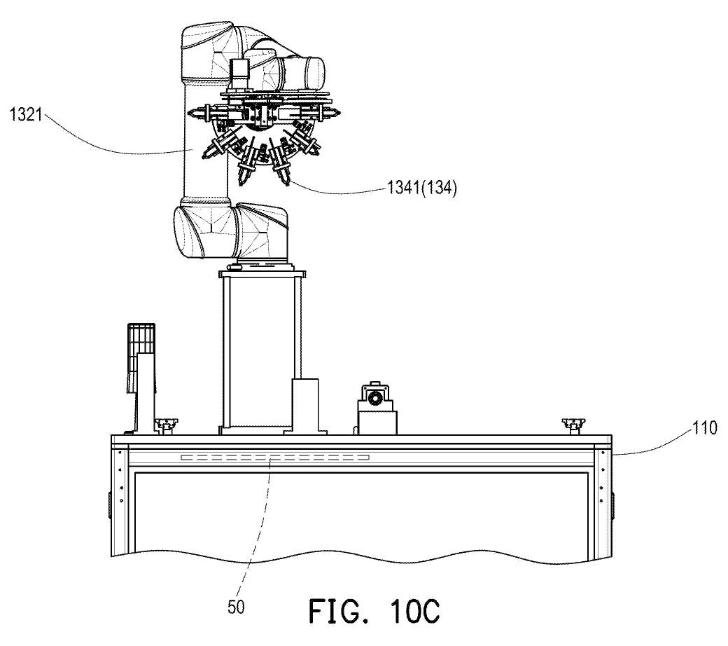

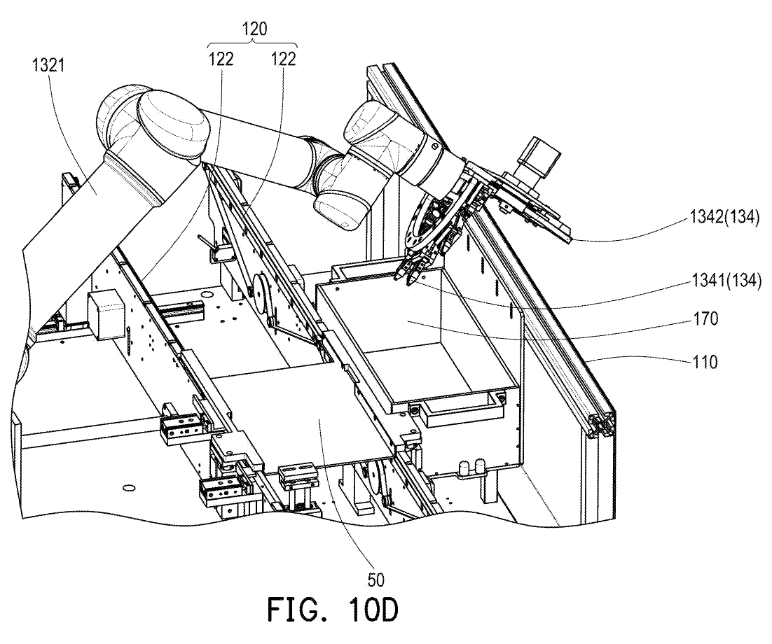

The following describes the operation process of the circuit board processing equipment 100 of this embodiment. FIG. 10A, FIG. 10B, FIG. 10C, and FIG. 10D illustrate the operation process of the circuit board processing equipment of FIG. 1. First, as shown in FIG. 10A, the circuit board 50 is conveyed to the working position by the track portion 120, and the circuit board 50 is clamped by the clamping device 160. Next, as shown in FIG. 10B, the robotic arm 1321 directs the tape assembly 1342 of the circuit board processing module 134 toward the circuit board 50, and the tape assembly 1342 adheres the dustproof film 502 on the circuit board 50 as shown in FIG. 6A to FIG. 6B. Next, as shown in FIG. 10C, the robotic arm 1321 directs the clamping claw 1341 of the circuit board processing module 134 toward the circuit board 50, and the clamping claw 1341 clamps the protective cover 501 on the circuit board 50 as shown in FIG. 5A to FIG. 5B. Next, as shown in FIG. 10D, the clamping claw 1341 of the circuit board processing module 134 is moved above the waste box 170 by the robotic arm 1321 and the protective cover 501 is placed into the waste box 170. In other embodiments, the order in which the tape assembly 1342 and the circuit board processing module 134 are moved above of the circuit board 50 may be opposite to that of the present embodiment, that is, the clamping claw 1341 of the circuit board processing module 134 first clamps the protective cover 501 on the circuit board 50. The tape 1342d of the tape assembly 1342 then adheres the dustproof film 502 on the circuit board 50. Finally, the circuit board 50 is moved away from the circuit board processing device 130 through the track portion 120.

To sum up, the circuit board processing equipment of the disclosure automatically drives the clamping claw to remove the protective cover on the circuit board using a driving part, and/or automatically drives the tape assembly to peel off the dustproof film on the circuit board using a driving part. Accordingly, there is no need to manually remove the protective cover and peel off the dustproof film, and the efficiency of processing the circuit board may be improved.

What is claimed is:

1. A circuit board processing equipment, for a circuit board, wherein a protective cover and a dustproof film are provided on the circuit board, the circuit board processing equipment comprising:
a base;
a track portion, disposed on the base and the circuit board being conveyed via the track portion; and
a circuit board processing device, including a driving part , a clamping claw and a tape assembly, wherein the driving part is disposed on the base and is coupled to the clamping claw and the tape assembly, the protective cover is removed from the circuit board via the clamping claw being driven, and the dustproof film is adhered to the tape assembly and the dustproof film is removed from the circuit board via the tape assembly being driven by the driving part.

2. The circuit board processing equipment according to claim 1, wherein the driving part includes a robotic arm, the clamping claw and the tape assembly are coupled to the robotic arm.

3. The circuit board processing equipment according to claim 1, wherein the driving part includes a bracket, the bracket includes two frames respectively extending in different directions, the clamping claw and the tape assembly are respectively disposed on each of the two frames.

4. The circuit board processing equipment according to claim 2, wherein the robotic arm is coupled to the clamping claw and the clamping claw is driven to move corresponding to the protective cover.

5. The circuit board processing equipment according to claim 1, wherein the driving part includes a cylinder connected to the clamping claw and the protective cover is clamped via the clamping claw being driven.

6. The circuit board processing equipment according to claim 2, wherein the protective cover includes a plurality of protective covers, the clamping claw includes a plurality of clamping claws, the driving part includes a plurality of cylinders, the cylinders are respectively connected to the clamping claws, the clamping claws is driven to move above the protective covers via the robotic arm and the protective covers are sequentially removed from the circuit board via the clamping claws being controlled through the cylinders.

7. The circuit board processing equipment according to claim 6, wherein the driving part includes an arc-shaped frame, the clamping claws are sequentially disposed on the arc-shaped frame.

8. The circuit board processing equipment according to claim 1, further comprises a driving device, wherein the track portion includes two tracks, the driving device is connected to the track portion, and a distance between the two tracks is adjusted via the two tracks being driven to move relative to each other by the driving device.

9. The circuit board processing equipment according to claim 1, further comprises a clamping device and a driving device, wherein the clamping device is disposed on the track portion, the driving device is connected to the clamping device, and the circuit board is clamped on the track portion via the clamping device being driven by the driving device.

10. The circuit board processing equipment according to claim 1, further comprising a waste box, wherein the waste box is disposed on the base, the protective cover is moved into the waste box via the clamping claw being driven by the driving part.

11. The circuit board processing equipment according to claim 2, wherein the robotic arm is coupled to the tape assembly and the tape assembly is driven to move corresponding to the dustproof film by the robotic arm.

12. The circuit board processing equipment according to claim 1, wherein the tape assembly includes a feed reel, a recovery reel, a tape support and a tape, the tape is partially wound around the feed reel and the recovery reel, and a portion of the tape located between the feed reel and the recovery reel is supported by the tape support.

13. The circuit board processing equipment according to claim 12, wherein the tape support is provided with a support plane, the tape is supported by the support plane.

14. The circuit board processing equipment according to claim 12, wherein the driving part includes a motor, the motor is connected to the recovery reel, and different portions of the tape are rotated and driven to be supported by the tape support in sequence via the recovery reel being driven by the motor.

15. The circuit board processing equipment according to claim 12, wherein the tape assembly further includes a sensing device, whether the tape is supported by the tape support is determined via the tape being sensed by the sensing device.

16. The circuit board processing equipment according to claim 15, wherein the sensing device includes an optical sensor disposed between the tape support and the feed reel, or disposed between the tape support and the recovery reel.

17. A circuit board processing equipment, for a circuit board, wherein a protective cover is provided on the circuit board, the circuit board processing equipment comprising:
a base;
a track portion, disposed on the base and the circuit board being conveyed via the track portion;
a circuit board processing device, including a driving part and a plurality of clamping claws; and
a waste box, disposed on the base and adjacent to the track portion;
wherein, the driving part is disposed on the base and is coupled to the clamping claws, the protective cover is removed from the circuit board and the protective cover is placed in the waste box via the clamping claws being driven by the driving part.

18. The circuit board processing equipment according to claim 17, wherein the driving part includes an arc-shaped frame, the clamping claws are sequentially disposed on the arc-shaped frame.

19. A circuit board processing equipment, for a circuit board, wherein a dustproof film is provided on the circuit board, the circuit board processing equipment comprising:
a base;
a track portion, disposed on the base and the circuit board being conveyed via the track portion; and
a circuit board processing device, including a driving part and a tape assembly, wherein the driving part is disposed on the base and is coupled to the tape assembly, the dustproof film is adhered to the tape assembly and the dustproof film is removed from the circuit board via the tape assembly being driven by the driving part.

20. The circuit board processing equipment according to claim 19, wherein the tape assembly includes a feed reel, a recovery reel, a tape support and a tape, the tape is partially wound around the feed reel and the recovery reel, and a portion of the tape located between the feed reel and the recovery reel is supported by the tape support.
